(19) United States
(12) Patent Application Publication
(10) Pub. No.: US 2012/0097239 A1
(43) Pub. Date: Apr. 26, 2012

(54) METHOD FOR ROUGHENING SUBSTRATE SURFACE, METHOD FOR MANUFACTURING PHOTOVOLTAIC DEVICE, AND PHOTOVOLTAIC DEVICE

(75) Inventors: Takehiko Sato, Tokyo (JP); Kunihiko Nishimura, Tokyo (JP); Daisuke Niinobe, Tokyo (JP); Shuichi Hiza, Tokyo (JP); Shigeru Matsuno, Tokyo (JP)

(73) Assignee: MITSUBISHI ELECTRIC CORPORATION, Tokyo (JP)

(21) Appl. No.: 13/378,187

(22) PCT Filed: Mar. 30, 2010
(86) PCT No.: PCT/JP2010/055735

§ 371 Date: Dec. 14, 2011

(30) Foreign Application Priority Data
Jul. 14, 2009 (JP) 2009-165880

(51) Int. Cl. H01L 31/0236; H01L 31/0232; H01L 31/18; B29D 11/00

(52) U.S. Cl. 136/256; 216/24; 438/71; 257/E31.13

(57) ABSTRACT

To include a first step of forming a protection film on a surface of a translucent substrate, a second step of exposing the surface of the translucent substrate by forming a plurality of openings arranged regularly at a certain pitch in the protection film, a third step of forming parabolic irregularities including substantially hemispherical depressions arranged substantially uniformly on the surface of the translucent substrate by performing isotropic etching by using the protection film having the openings formed as a mask and under conditions in which the protection film has resistance to the surface of the translucent substrate on which the protection film is formed, and a fourth step of removing the protection film, wherein at the fourth step, the isotropic etching is continued after formation of the parabolic irregularities to separate the protection film from the translucent substrate and round apexes of protruded portions in the parabolic irregularities.

### FIELD

The present invention relates to a method for roughening a substrate surface, a method for manufacturing a photovoltaic device, and a photovoltaic device and, more particularly to a method for roughening a substrate surface that enables to increase efficiency by reducing optical reflection through scattering of incident light and causing light to be efficiently absorbed into a device, and a method for manufacturing a photovoltaic device and a photovoltaic device using this method for roughening a substrate surface.

### BACKGROUND

Thin-film silicon solar cells which are photovoltaic devices include superstrate thin-film silicon solar cells and substrate thin-film silicon solar cells, and the superstrate thin-film silicon solar cells are often used in common solar cells other than flexible solar cells. The superstrate thin-film silicon solar cell includes a transparent conductive layer, one or many photovoltaic layers having a pin junction, a transparent conductive layer, and a back overall electrode made of a metallic material laminated in this order on a side opposite from an acceptance surface of a translucent substrate such as glass. The substrate thin-film silicon solar cell includes a transparent conductive layer, one or many photovoltaic layers having a pin junction, a transparent conductive layer, and a grid electrode on a substrate such as metal, and has an acceptance surface on the grid electrode side.

To increase efficiency of a solar cell, it is necessary to cause incident light on the solar cell to be efficiently absorbed by a photovoltaic layer. However, a texture structure is usually formed also in such thin-film solar cells to prevent light reflection on an incidence surface. Because it is difficult to form a texture structure on a light incidence side of the superstrate thin-film silicon solar cell from the viewpoint of weatherability, the texture structure is usually formed between a glass substrate and a photovoltaic layer. Texture-structure formation methods include a method of forming a texture structure on a glass substrate as described in Patent Literature 1, for example, and a method of forming a texture structure on a transparent conductive layer as described in Patent Literature 2, for example.

Patent Literature 1 describes a method that enables to form irregularities on a surface of a translucent substrate by forming a particulate pattern of tin oxide on the translucent substrate through spraying or the like and etching the translucent substrate using the pattern as an etching mask. Patent Literature 2 describes a method that enables to form an irregular surface on a transparent conductive layer by forming the transparent conductive layer on a glass substrate through vapor deposition and then etching the transparent conductive layer with an acid solution. A method that enables to form irregularities utilizing film formation conditions of a transparent conductive layer can be also used as a method of forming a texture structure on a transparent conductive layer.

As other methods of forming a texture structure on a substrate, Patent Literatures 3 and 4 describe methods that enable to form irregularities on a surface of a transparent insulating substrate through sandblasting, for example. Meanwhile, Patent Literature 5 describes as a way to reduce optical reflectivity of a crystalline silicon solar cell, a method that enables to form irregularities in hemispherical shapes by forming a dotted opening on a silicon substrate with laser by using a thin film as a mask and then performing isotropic wet etching.

When irregularities are formed on a glass substrate on a side of a photovoltaic layer, there is a problem that the irregularities greatly affect characteristics of a thin-film silicon photovoltaic layer. Irregularities used in a crystalline silicon solar cell are usually in pyramid structures having protruded portions formed by rectilinear inclined planes, in inverted pyramid structures having depressed portions in pyramid shapes, and the like. When the irregularities are formed by curved surfaces, protruding irregularities in which protruded portions have round curved surfaces, or irregularities in which depressed portions have parabolic round curved surfaces are conceivable.

While effects of reducing optical reflectivity are expected in all the shapes, some of the shapes lower characteristics. That is, when the inclined planes of the irregularities are constituted by flat surfaces or when the protruding irregularities are provided, depressed portions have a key-shaped portion in which two planes intersect with each other. It is confirmed that, when there is a key-shape portion in which two planes intersect with each other on a photovoltaic-layer formation plane in a thin-film silicon solar cell, a portion in which silicon grows on the respective planes intersecting with each other is produced during formation of upper photovoltaic layers, and a defect easily occurs at the intersection, which lowers the characteristics. Therefore, when the irregularities are formed between a glass substrate and a photovoltaic layer, a structure having parabolic irregularities arranged regularly is desirable.

### CITATION LIST

### Patent Literatures

Patent Literature 1: Japanese Patent Application Laid-open No. S59-123279
Patent Literature 2: Japanese Patent Application Laid-open No. 2003-115599
Patent Literature 3: Japanese Patent Application Laid-open No. H09-199745
Patent Literature 4: Japanese Patent Application Laid-open No. H07-122764
Patent Literature 5: Japanese Patent Application Laid-open No. 2008-227070

### SUMMARY

### Technical Problem

In the method of forming a pattern with particles dispersed on a translucent substrate and etching the translucent substrate using the pattern as an etching mask as described in Patent Literature 1, edges of depressed portions can be rounded by etching; however, shapes of the irregularities cannot be controlled. Besides, in an area where the particles are sparsely dispersed, the depressed portions are flat and an effect of preventing light reflection is small. On the other hand, in an area where the particles are thickly dispersed, the portion where the silicon grows on the respective planes intersecting with each other during formation of photovoltaic layers is produced, which leads to lower characteristics.

In the method of forming irregularities on a transparent conductive layer as described in Patent Literature 2, shapes of the irregularities cannot be sufficiently controlled. Accordingly, the portion where the silicon grows on the respective planes intersecting with each other during formation of photovoltaic layers is produced, and a defect in the silicon occurs, resulting in lower characteristics. Besides, irregularities having a depth of a certain aspect ratio with respect to a pitch of the irregularities and having a large effect of reducing optical reflectivity cannot be formed by this method.

The method of forming irregularities on the surface of a substrate through sandblasting as described in Patent Literature 3 or 4 cannot sufficiently control shapes of the irregularities. Therefore, the portion where the silicon grows on the respective planes intersecting with each other during formation of photovoltaic layers, is produced, and a defect in the silicon occurs, which leads to lower characteristics.

When the method of forming a dotted opening on a silicon substrate with laser by using a thin film as a mask and then performing the isotropic wet etching as described in Patent Literature 5 is applied to a glass substrate of a thin-film solar cell, texture protruded portions are angular-shaped and a defect easily occurs in silicon thin films as photovoltaic layers during formation of the photovoltaic layers, which may lower the characteristics.

The present invention has been achieved in view of the above problems, and an object of the present invention is to provide a method for roughening a substrate surface capable of uniformly performing fine roughening of a substrate surface in a manner that does not induce occurrence of a defect in semiconductor layers formed as upper layers, and a method for manufacturing a photovoltaic device and a photovoltaic device using the method for roughening a substrate surface.

### Solution to Problem

In order to solve the aforementioned problems and attain the aforementioned object, according to an aspect of the present invention, a method for roughening a substrate surface is provided with: a first step of forming a protection film on a surface of a translucent substrate; a second step of exposing the surface of the translucent substrate by forming a plurality of openings arranged regularly at a certain pitch in the protection film; a third step of forming parabolic irregularities including substantially hemispherical depressions arranged substantially uniformly on the surface of the translucent substrate by performing isotropic etching by using the protection film having the openings formed as a mask and under conditions in which the protection film has resistance to the surface of the translucent substrate on which the protection film is formed; and a fourth step of removing the protection film, wherein at the fourth step, the isotropic etching is continued after formation of the parabolic irregularities to separate the protection film from the translucent substrate and round apexes of protruded portions in the parabolic irregularities.

### Advantageous Effects of Invention

According to the present invention, fine roughening of a substrate surface can be uniformly performed in a manner that does not induce occurrence of a defect in semiconductor layers formed as upper layers.

### BRIEF DESCRIPTION OF DRAWINGS

FIG. 1 is a cross-sectional view schematically depicting a glass substrate having a surface thereof roughened by a method for roughening a substrate surface according to a first embodiment of the present invention.

FIG. 2 is a cross-sectional view schematically depicting a configuration of a thin-film silicon solar cell according to the first embodiment of the present invention.

FIG. 3 is a flowchart for explaining a method for manufacturing the thin-film silicon solar cell according to the first embodiment of the present invention.

FIG. 4-1 is a cross-sectional view for explaining the method for manufacturing the thin-film silicon solar cell according to the first embodiment of the present invention.

FIG. 4-2 is a cross-sectional view for explaining the method for manufacturing the thin-film silicon solar cell according to the first embodiment of the present invention.

FIG. 4-3 is a cross-sectional view for explaining the method for manufacturing the thin-film silicon solar cell according to the first embodiment of the present invention.

FIG. 4-4 is a cross-sectional view for explaining the method for manufacturing the thin-film silicon solar cell according to the first embodiment of the present invention.

FIG. 4-5 is a cross-sectional view for explaining the method for manufacturing the thin-film silicon solar cell according to the first embodiment of the present invention.

FIG. 4-6 is a cross-sectional view for explaining the method for manufacturing the thin-film silicon solar cell according to the first embodiment of the present invention.

FIG. 4-7 is a cross-sectional view for explaining the method for manufacturing the thin-film silicon solar cell according to the first embodiment of the present invention.

FIG. 4-8 is a cross-sectional view for explaining the method for manufacturing the thin-film silicon solar cell according to the first embodiment of the present invention.

FIG. 5 is a flowchart for explaining a method for manufacturing a thin-film silicon solar cell according to a second embodiment of the present invention.

FIG. 6-1 is a cross-sectional view for explaining a method for manufacturing the thin-film silicon solar cell according to the second embodiment of the present invention.

FIG. 6-2 is a cross-sectional view for explaining the method for manufacturing the thin-film silicon solar cell according to the second embodiment of the present invention.

FIG. 6-3 is a cross-sectional view for explaining the method for manufacturing the thin-film silicon solar cell according to the second embodiment of the present invention.

FIG. 6-4 is a cross-sectional view for explaining the method for manufacturing the thin-film silicon solar cell according to the second embodiment of the present invention.

FIG. 6-5 is a cross-sectional view for explaining the method for manufacturing the thin-film silicon solar cell according to the second embodiment of the present invention.

FIG. 6-6 is a cross-sectional view for explaining the method for manufacturing the thin-film silicon solar cell according to the second embodiment of the present invention.

FIG. 6-7 is a cross-sectional view for explaining the method for manufacturing the thin-film silicon solar cell according to the second embodiment of the present invention.

FIG. 6-8 is a cross-sectional view for explaining the method for manufacturing the thin-film silicon solar cell according to the second embodiment of the present invention.

FIG. 6-9 is a cross-sectional view for explaining the method for manufacturing the thin-film silicon solar cell according to the second embodiment of the present invention.

### DESCRIPTION OF EMBODIMENTS

Exemplary embodiments of a method for roughening a substrate surface, a method for manufacturing a photovoltaic device, and a photovoltaic device according to the present invention will be explained below in detail with reference to the accompanying drawings. The present invention is not limited to the following descriptions and various modifications can be appropriately made without departing from the scope of the invention. In addition, in the drawings explained below, scales of respective members may be shown differently from those in practice to facilitate understanding, and the same applies to the relationships between the drawings.

### First Embodiment

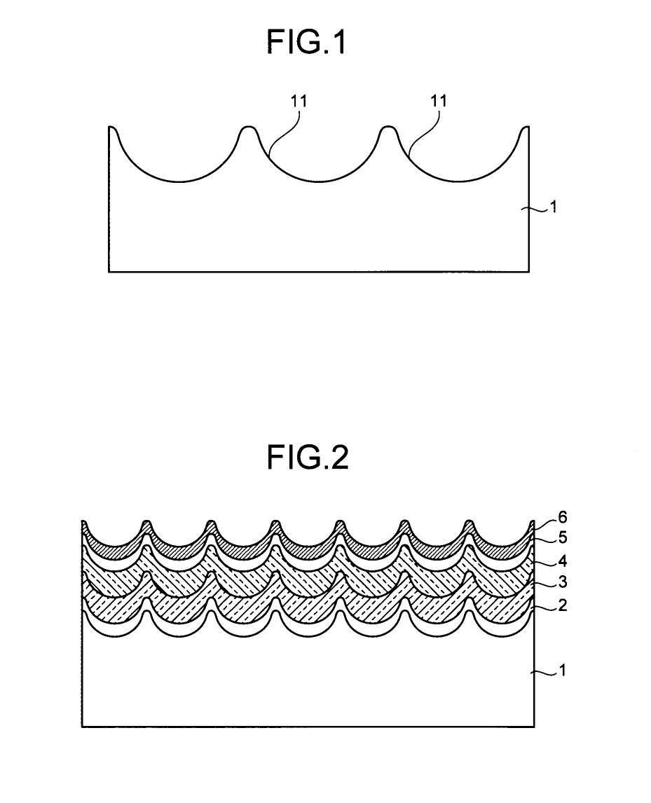

FIG. 1 is a cross-sectional view schematically depicting a glass substrate 1 having a surface thereof roughened by a method for roughening a substrate surface according to a first embodiment of the present invention. The glass substrate 1 is a translucent substrate for a thin-film silicon solar cell, which is a photovoltaic device. On a surface of the glass substrate 1 on one side, substantially hemispherical texture depressions 11 with an average inter-hole pitch of about 5 micrometers are arranged substantially uniformly as a texture structure to form parabolic irregularities. Here, a texture structure indicates an irregular structure formed on a surface of the glass substrate 1 and is effective for suppression of reflected light. By forming the texture structure, the reflected light can be suppressed and photoelectric conversion efficiency can be improved. The parabolic irregularities have hemispherical shapes in which a height difference in the irregularities (an average of heights from bottoms of depressed portions to apexes of protruded portions) is about a half of the inter-hole pitch. Such a texture structure of parabolic irregularities has low optical reflectivity and achieves a high optical confinement effect when a thin-film silicon solar cell is formed.

The texture structure formed on the surface of the glass substrate 1 includes the irregularities in parabolic shapes, and the apexes of the protruded portions in the parabolic irregularities have rounded smooth shapes. This prevents occurrence of a defect due to the texture structure in photovoltaic layers formed as upper layers on the glass substrate 1 with a transparent electrode layer interposed therebetween and also prevents photoelectric conversion characteristics from lowering due to the texture structure, when a thin-film silicon solar cell is formed by using the glass substrate 1.

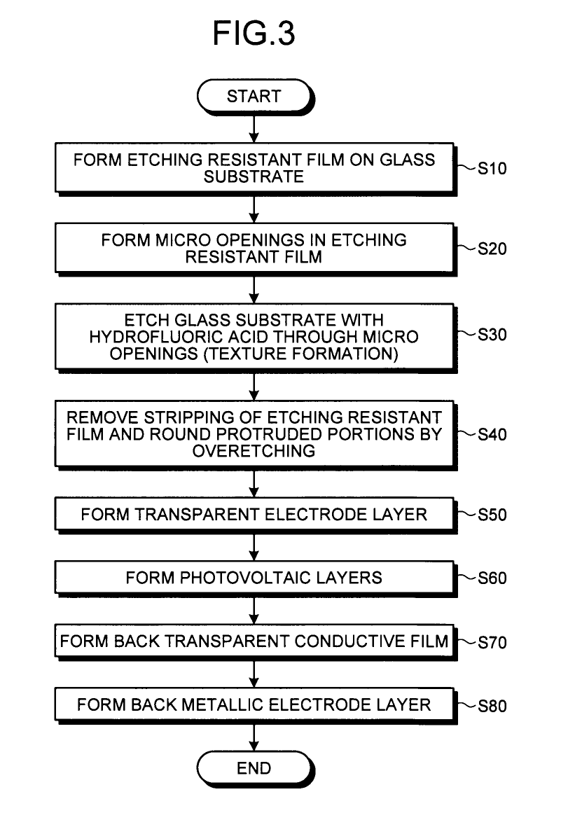

FIG. 2 is a cross-sectional view schematically depicting a configuration of a thin-film silicon solar cell according to the first embodiment, which is formed by a method for manufacturing a photovoltaic device according to the present embodiment by using the glass substrate 1 as shown in FIG. 1. As shown in FIG. 2, the thin-film silicon solar cell according to the present embodiment has a structure in which the glass substrate 1 as a translucent substrate, a transparent electrode layer 2 formed on the glass substrate 1 to be a first electrode layer, a first photovoltaic layer 3 that is a first thin-film semiconductor layer formed on the transparent electrode layer 2, a second photovoltaic layer 4 that is a second thin-film semiconductor layer formed on the first photovoltaic layer 3, a back transparent conductive film 5 formed on the second photovoltaic layer 4, and a back metallic electrode layer 6 formed on the back transparent conductive film 5 to be a second electrode layer are laminated one above another in this order.

As the translucent substrate, various insulating substrates having translucency such as glass, transparent resin, plastic, and quartz are used. In the present embodiment, the glass substrate 1 is used.

The transparent electrode layer 2 is made of a translucent conductive material, and a transparent conductive film such as tin oxide (SnO₂), zinc oxide (ZnO), or indium tin oxide (ITO) can be used therefor. Here, a very small quantity of impurities can be added to the film. The transparent electrode layer 2 is formed in a shape according to the texture structure on the surface of the glass substrate 1, and the texture structure has a function to disperse incident sunlight, thereby increasing light use efficiency in the first photovoltaic layer 3.

The transparent electrode layer 2 can be manufactured by various methods such as a sputtering method, an electron beam deposition method, an ambient-pressure chemical vapor deposition (CVD) method, a low-pressure CVD method, a metal organic chemical vapor deposition (MOCVD) method, a sol-gel method, a printing method, and a spraying method.

A crystalline silicon-system semiconductor film or an amorphous silicon-system semiconductor film is used as the first photovoltaic layer 3 and the second photovoltaic layer 4, for example, and each of the photovoltaic layers is made of a semiconductor film in a three-layer structure including a p-type, an i-type, and an n-type arranged from the side of the transparent electrode layer 2. That is, each of the photovoltaic layers is a laminated film in which a p-type semiconductor layer as a first conductive semiconductor layer, an i-type semiconductor layer as a second conductive semiconductor layer, and an n-type semiconductor layer as a third conductive semiconductor layer are laminated in this order from the side of the transparent electrode layer 2. These photovoltaic layers are usually deposited by using a plasma CVD method, a thermal CVD method, or the like.

In the present embodiment, a p-type semiconductor layer, an i-type semiconductor layer, and an n-type semiconductor layer each being made of amorphous silicon (α-Si) are included as the first photovoltaic layer 3. An p-type semiconductor layer, an i-type semiconductor layer, and an n-type semiconductor layer each being made of microcrystalline silicon are included as the second photovoltaic layer 4. The first photovoltaic layer 3 is 500 micrometers thick, and the second photovoltaic layer 4 is 2.5 micrometers thick, which form photovoltaic layers in a tandem structure having a total thickness of 3 micrometers.

The back transparent conductive film 5 is made of a translucent conductive material, and a transparent conductive film such as tin oxide (SnO₂), zinc oxide (ZnO), or ITO can be used therefor. A very small quantity of impurities can be added to the back transparent conductive film 5. The back transparent conductive film 5 prevents diffusion of elements from the back metallic electrode layer 6 to the second photovoltaic layer 4. The back transparent conductive film 5 can be manufactured by a known method such as the sputtering method, the ambient-pressure CVD method, a reduced-pressure CVD method, the MOCVD method, the electron beam deposition method, the sol-gel method, an electrocrystallization method, or the spraying method.

The back metallic electrode layer 6 functions as a back electrode and also functions as a reflection layer that reflects light not absorbed by the photoelectric conversion layer and returns the unabsorbed light back to the photoelectric conversion layer, thereby contributing to improvement in photoelectric conversion efficiency. Therefore, the back metallic electrode layer 6 having higher optical reflectivity and higher conductivity is more favorable. The back metallic electrode layer 6 can be made of a metallic material having high visible light reflectivity such as silver (Ag), aluminum (Al), titanium (Ti), or palladium, an alloy of these metallic materials, a nitride of these metallic materials, or an oxide of these metallic materials. Specific materials of the back metallic electrode layer 6 are not particularly limited and appropriate materials can be selected from know materials.

As described above, in the thin-film silicon solar cell according to the first embodiment, the substantially hemispherical texture depressions 11 having the average inter-hole pitch of about 5 micrometers are provided substantially uniformly as the texture structure to form the parabolic irregularities on the surface of the glass substrate 1 on one side. With the texture structure of the parabolic irregularities, low optical reflectivity and a satisfactory optical confinement effect can be obtained.

In these parabolic irregularities, the apexes of the protruded portions of the irregularities have rounded smooth shapes. This prevents occurrence of a defect in the photovoltaic layers caused by the texture structure and also prevents reduction in the photoelectric conversion characteristics due to the texture structure. Therefore, with the thin-film silicon solar cell according to the first embodiment, a thin-film silicon solar cell having high photoelectric conversion characteristics is realized.

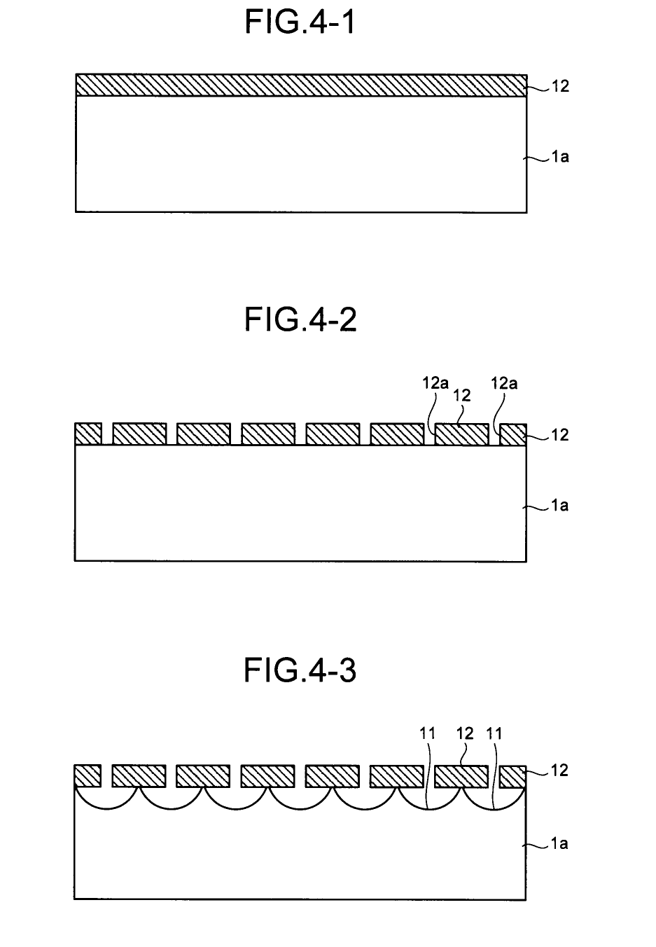

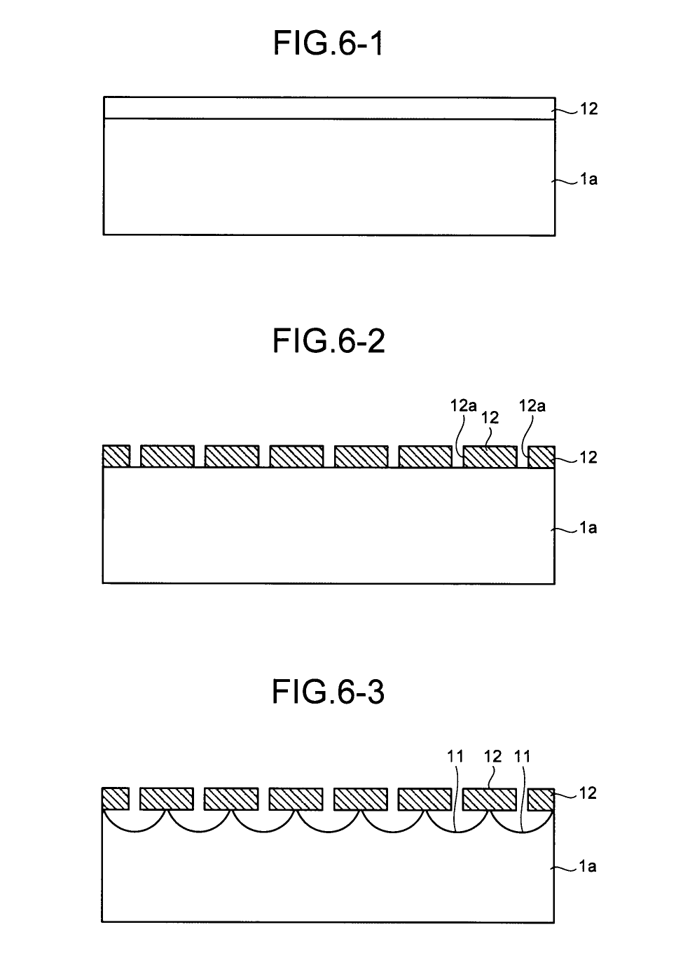

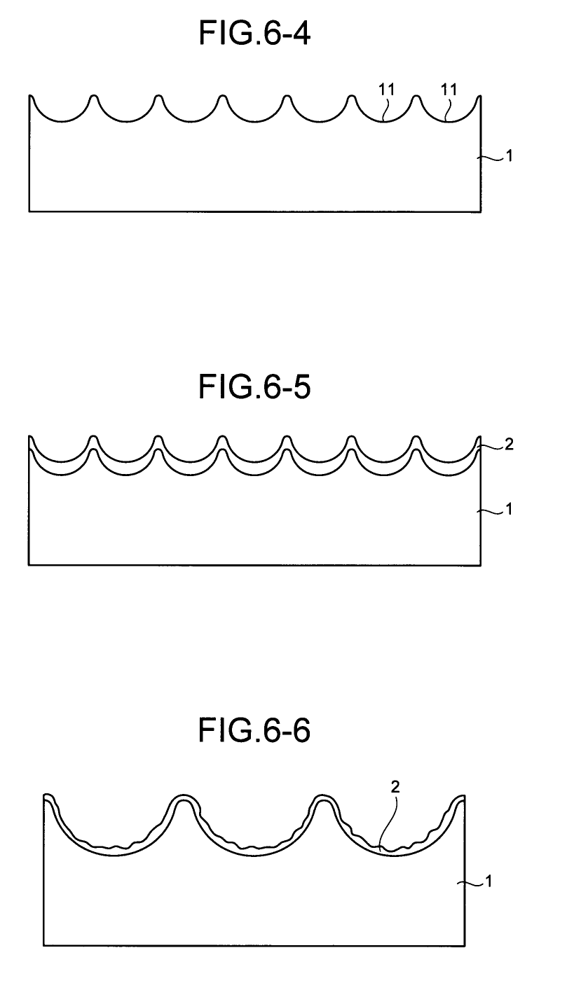

A method for manufacturing the thin-film silicon solar cell configured as described above according to the present embodiment will be explained below with reference to FIGS. 3 and 4-1 to 4-8. FIG. 3 is a flowchart for explaining a method for manufacturing the thin-film silicon solar cell according to the first embodiment. FIGS. 4-1 to 4-8 are cross-sectional views for explaining the method for manufacturing the thin-film silicon solar cell according to the first embodiment.

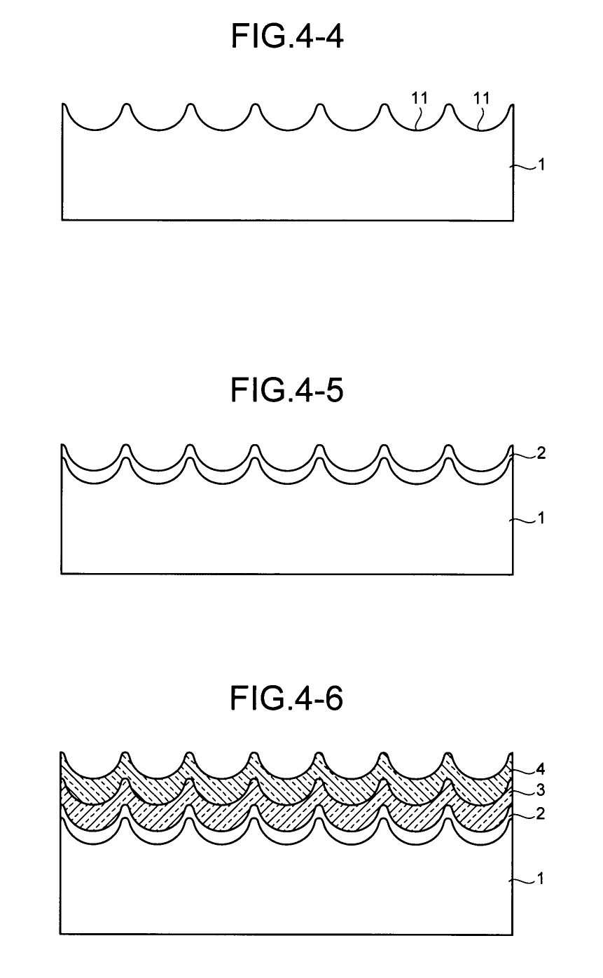

A glass substrate 1a, which is a target for roughening of a substrate surface, is first cleaned and a film (hereinafter, etching resistant film) 12 having etching resistance to etching, which is described later, is formed on a surface thereof on one side as a protection film (Step S10, FIG. 4-1).

In the present embodiment, an amorphous silicon (α-Si) film is formed as the etching resistant film 12 by the plasma CVD method using silane gas and hydrogen gas. The amorphous silicon is favorable as an etching mask for the glass substrate 1a of the thin-film silicon solar cell because it has satisfactory etching resistance to hydrofluoric acid when the hydrofluoric acid is used in the etching described later. The amorphous silicon can be formed by the same device as that used in a later process of forming a photovoltaic layer made of a silicon thin film, which reduces processing costs.

The etching resistant film 12 is preferably 50 nanometers to 300 nanometers thick. When the thickness of the etching resistant film 12 is equal to or larger than 50 nanometers, the film reliably functions as an etching resistant film even if the etching resistant film is etched to a certain degree while etching is performed at a later step to one surface of the glass substrate 1a where the etching resistant film 12 is formed. When the thickness of the etching resistant film 12 is equal to or smaller than 300 nanometers, micro hole processing can be reliably performed to the etching resistant film 12 at a later step.

The micro hole processing is then performed to the etching resistant film 12 through lasering. That is, a plurality of openings arranged regularly at a certain pitch are formed in the etching resistant film 12 through lasering. In the present embodiment, a laser beam having an ultraviolet wavelength is applied to the etching resistant film 12 to form a plurality of micro openings 12a that are about 1 micrometer in diameter in the etching resistant film 12, at corners of regular triangles arranged at a 5-μm pitch, for example (Step S20, FIG. 4-2). Silicon-system thin films have strong absorption of relatively-short wavelength light such as ultraviolet rays or visible rays. Accordingly, the laser having an ultraviolet wavelength is favorable as a laser to be used to form the micro openings 12a.

The laser light has a spot diameter of about 1 micrometer to 5 micrometers, and the pitch of the micro openings 12a is about 2 micrometers to 10 micrometers. For example, when the spot diameter of the laser light is about 1 micrometer, the pitch of the micro openings 12a is preferably equal to or larger than 2 micrometers to perform etching through the micro openings 12a at the etching step described later until the substantially hemispherical texture depressions 11 contact with each other, thereby forming the parabolic irregularities. While etching in a lateral direction from the micro openings 12a is required to form the parabolic irregularities during isotropic etching described later, appropriate parabolic irregularities can be formed when the pitch of the micro openings 12a is equal to or larger than 2 micrometers because the spot diameter of the laser light usually has a lower limit of about 1 micrometer. Because long time is required to form the irregularities if the pitch of the micro openings 12a is too large, an upper limit of the pitch of the micro openings 12a is about 10 micrometers at a maximum, preferably about 5 micrometers.

Etching is then conducted to the surface of the glass substrate 1a on the side where the etching resistant film 12 is formed, by using the etching resistant film 12 subjected to the micro hole processing as a mask, thereby forming the substantially hemispherical texture depressions 11 (Step S30, FIG. 4-3). As the etching, wet etching using hydrofluoric acid is conducted, for example, which is performed by dipping the surface of the glass substrate 1a on the side where the etching resistant film 12 is formed into hydrofluoric acid. The hydrofluoric acid isotropically etches areas where the micro openings 12a are formed on the surface of the glass substrate 1a on the side where the etching resistant film 12 is formed and the surrounding areas through the micro openings 12a, thereby forming the substantially hemispherical texture depressions 11. In this way, the parabolic irregularities are formed on the surface of the glass substrate 1a, resulting in a texture structure.

When film stripping easily occurs during the etching of the amorphous silicon thin film as the etching resistant film 12 with the hydrofluoric acid, the surface of the glass substrate 1a can be previously roughened through sandblasting or the like.

Subsequently, removal of the etching resistant film 12 and rounding of the apexes of the protruded portions in the parabolic irregularities are performed (Step S40, FIG. 4-4). In this example, the isotropic etching with the hydrofluoric acid is continued after the formation of the parabolic irregularities to conduct overetching. The overetching is conducted until the etching resistant film 12 separates from the glass substrate 1a because of elimination of a contact portion between the etching resistant film 12 and the glass substrate 1a and also until the shapes of the apexes of the protruded portions in the parabolic irregularities are smoothly rounded and have no sharp protruding portions. This causes the etching resistant film 12 to be separated from the glass substrate 1a and removed, resulting in the glass substrate 1 having the texture structure formed. However, treatment with a mixture of the hydrofluoric acid and nitric acid can be also used after the overetching when the etching resistant film cannot be removed only by the overetching or to prevent occurrence of film stripping.

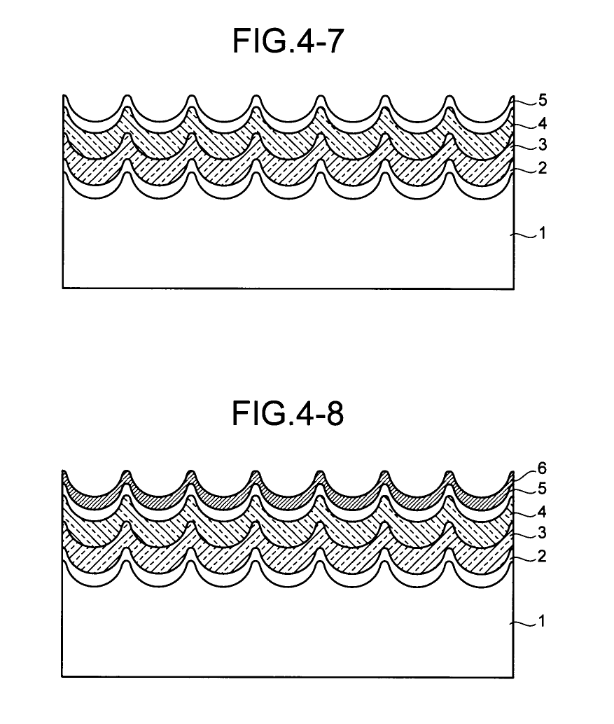

The transparent electrode layer 2 is then formed by a known method on the surface of the glass substrate 1a on which the parabolic irregularities are formed (Step S50, FIG. 4-5). For example, the transparent electrode layer 2 made of a zinc oxide (ZnO) film is formed on the glass substrate 1a by the sputtering method. Other methods such as the CVD method can be used as the film formation method.

A p-type semiconductor layer, an i-type semiconductor layer, and an n-type semiconductor layer each being made of amorphous silicon (α-Si) are then laminated on the transparent electrode layer 2 one above another by the plasma CVD method, for example, as the first photovoltaic layer 3. A p-type semiconductor layer, an i-type semiconductor layer, and an n-type semiconductor layer each being made of microcrystalline silicon are then laminated on the first photovoltaic layer 3 one above another by the plasma CVD method, for example, as the second photovoltaic layer 4 (Step S60, FIG. 4-6). In the present embodiment, photovoltaic layers in a tandem structure having a total thickness of 3 micrometers including the first photovoltaic layer 3 which is 500 micrometers thick and the second photovoltaic layer 4 which is 2.5 micrometers thick are formed.

Here, the parabolic irregularities as the texture structure are formed on the surface of the glass substrate 1, and the transparent electrode layer 2 which is a formation surface for the photovoltaic layers has a corresponding surface shape. If inclined planes of the irregularities are constituted by flat surfaces or protruding irregularities are formed in the texture structure on the formation surface for the photovoltaic layers, the depressed portions have a key-shaped portion in which two planes intersect with each other. If there is a key-shaped portion in which the two planes intersect with each other on the formation surface for the photovoltaic layers in a thin-film silicon solar cell, a portion in which silicon grows on the respective planes intersecting with each other is produced during formation of the upper photovoltaic layers, and a defect easily occur at the intersection, resulting in reduced photoelectric conversion characteristics.

However, in the present embodiment, the parabolic irregularities are formed on the surface of the glass substrate 1 and the apexes of the protruded portions in the parabolic irregularities are rounded to have rounded smooth shapes. Besides, the transparent electrode layer 2, which is the formation surface for the photovoltaic layers, has the corresponding surface shapes. Accordingly, occurrence of defects in the photovoltaic layers due to the texture structure on the formation surface for the photovoltaic layers as described above is prevented, and reduction in the photoelectric conversion characteristics due to the texture structure is prevented.

The back transparent conductive film 5 is then formed on the second photovoltaic layer 4 by a known method (Step S70, FIG. 4-7). The back transparent conductive film 5 made of a zinc oxide (ZnO) film is formed on the second photovoltaic layer 4 by the sputtering method, for example. Other film formation methods such as the CVD method can be used as the formation method.

The back metallic electrode layer 6 is then formed on the back transparent conductive film 5 by a known method (Step S80, FIG. 4-8). The back metallic electrode layer 6 made of a silver (Ag) film having high reflectivity is formed by the vapor deposition method on the back transparent conductive film 5, for example. With the above processes, the thin-film silicon solar cell according to the present embodiment shown in FIG. 2 is obtained.

A thin-film silicon solar cell manufactured through the above steps (an Example 1) and a thin-film silicon solar cell having the same configuration as that of the thin-film silicon solar cell of the Example 1 except that no texture structure is formed on the glass substrate 1 (a comparative example 1) were manufactured and then short-circuit current densities Jsc (mA/cm²) thereof were compared. As a result, the short-circuit current density of the thin-film silicon solar cell of the Example 1 improved by about 5% relative to that of the thin-film silicon solar cell of the comparative example 1. This confirmed an effect of improving the photoelectric conversion characteristics by the method for manufacturing a thin-film silicon solar cell according to the present embodiment.

As described above, in the method for roughening a solar cell substrate surface according to the first embodiment, the parabolic irregularities having the substantially hemispherical texture depressions 11 arranged substantially uniformly are formed as the texture structure on the surface of the glass substrate 1 on one side. The texture structure of the parabolic irregularities has lower optical reflectivity and achieves a greater optical confinement effect when the thin-film silicon solar cell is formed.

The apexes of the protruded portions in the parabolic irregularities are subjected to the rounding through etching to be rounded and accordingly have smoothly rounded shapes. In this way, when a thin-film silicon solar cell is formed by using the glass substrate 1, occurrence of defects caused by the texture structure in the photovoltaic layers formed above the glass substrate 1 with the transparent electrode layer 2 interposed therebetween can be prevented, and reduction in the photoelectric conversion characteristics due to the texture structure can be prevented. Therefore, by the method for roughening a solar cell substrate surface according to the first embodiment, the texture structure that enables to manufacture a thin-film silicon solar cell having high photoelectric conversion characteristics can be formed on the glass substrate 1.

As described above, in the method for manufacturing a thin-film silicon solar cell according to the first embodiment, the parabolic irregularities having the substantially hemispherical texture depressions 11 arranged substantially uniformly are formed as the texture structure on the surface of the glass substrate 1 on one side. The texture structure of the parabolic irregularities has lower optical reflectivity and achieves a greater optical confinement effect when the thin-film silicon solar cell is formed.

The apexes of the protruded portions in the parabolic irregularities are subjected to the rounding through etching to have smooth and rounded shapes. This enables to prevent occurrence of defects caused by the texture structure in the photovoltaic layers formed above the glass substrate 1 with the transparent electrode layer 2 interposed therebetween, and to prevent reduction in the photoelectric conversion characteristics due to the texture structure. Therefore, by the method for manufacturing a thin-film silicon solar cell according to the first embodiment, a thin-film silicon solar cell having high photoelectric conversion characteristics can be manufactured.

### Second Embodiment

In the first embodiment described above, the case where the laser processing is used as the method for forming the openings in the etching resistant film 12 has been explained. In a second embodiment of the present invention, a case where sandblasting is used as a method for forming the openings in the etching resistant film 12 will be explained.

In the second embodiment, the amorphous silicon thin film is formed on the glass substrate 1a as the etching resistant film 12 like in the first embodiment, and the openings are formed in the etching resistant film 12 by conducting dry sandblasting to the amorphous silicon thin film. In the dry sandblasting, sandblasting is performed by using aluminum oxide (Al₂O₃) blast abrasive grains #2000 and with a discharge pressure of 0.5 Mpa and an abrasive grain flow rate of 10 to 15 mg/min, for example, thereby forming the micro openings in the etching resistant film 12. After formation of the micro openings in the amorphous silicon thin film by the sandblasting, the parabolic irregularities are formed on the glass substrate 1a in the same manner as that in the first embodiment to form a thin-film silicon solar cell.

A thin-film silicon solar cell according to an Example 2 was formed by the method for manufacturing a thin-film silicon solar cell according to the second embodiment. Short-circuit current densities Jsc (mA/cm²) of the thin-film silicon solar cell according to the Example 2 and of the thin-film silicon solar cell according to the comparative example 1 of the first embodiment were compared.

In the thin-film silicon solar cell according to the Example 2, pitches and shapes of the parabolic irregularities on the glass substrate 1a vary as compared to the thin-film silicon solar cell according to the Example 1. Accordingly, the effect of reducing the reflectivity was smaller than in the thin-film silicon solar cell according to the first embodiment; however, there was an about 4% increase in the short-circuit current density relative to the comparative example 1. This confirmed an effect of improving the photoelectric conversion characteristics by the method for manufacturing a thin-film silicon solar cell according to the second embodiment.

### Third Embodiment

In a third embodiment of the present invention, a case where a silicon dioxide thin film is formed as the etching resistant film 12 by the plasma CVD method using silane gas, hydrogen gas, and carbon dioxide will be explained. A roughened surface configuration of a substrate and a configuration of a thin-film silicon solar cell formed in the third embodiment are the same as those in the first embodiment. A manufacturing method according to the third embodiment is the same as that in the first embodiment except for a step of forming a silicon dioxide thin film as the etching resistant film 12.

At the step of forming a silicon dioxide thin film in the third embodiment, formation is performed by flowing source gas composed of silane gas, hydrogen gas, and carbon dioxide using VHF (Very High Frequency) plasma CVD of 60 kilohertz under conditions of a substrate temperature of 170° C. and a gas pressure of 0.5 Torr, for example. Because the thin film of this system can be formed by the same device as that used in a later process of forming photovoltaic layers made of a silicon thin film, costs of manufacturing facilities can be reduced, thereby contributing to realization of an inexpensive thin-film silicon solar cell.

The plasma CVD method enables to form a silicon dioxide thin film having arbitrary oxygen content by adjusting a flow ratio between the carbon dioxide and the silane gas. When the silicon film is used as the etching resistant film, a silicon film containing no oxygen or silicon dioxide thin film having an oxygen content ratio as low as less than a small percent has low adhesion to the glass substrate. Accordingly, stripping easily occurs when the glass is etched after laser opening formation, which is explained later.

The silicon dioxide thin film having a low oxygen content ratio does not dissolve in an etching solution during glass etching. Accordingly, a stripped film remains in the etching solution and interferes with consecutive processing. In contrast, a silicon dioxide thin film having an oxygen content ratio as high as more than 50% has a high laser light transmission, which creates difficulty in the opening formation. Accordingly, a configuration having adhesion (stripping suppression) and being easy in laser opening formation can be realized by adjusting an oxygen content ratio in the silicon dioxide thin film to an appropriate value in a range of 10 to 50%, for example. After formation of the etching resistant film 12, the parabolic irregularities are formed on the glass substrate 1a to form a thin-film silicon solar cell in the same manner as in the first embodiment.

A thin-film silicon solar cell according to an Example 3 was formed by the method for manufacturing a thin-film silicon solar cell according to the third embodiment. Short-circuit current densities Jsc (mA/cm²) of the thin-film silicon solar cell according to the Example 3 and of that according to the comparative example 1 of the first embodiment were compared.

As a result, the short-circuit current density of the thin-film silicon solar cell according to the Example 3 improved by about 5.5% relative to that of the thin-film silicon solar cell according to the comparative example 1. This confirmed an effect of improving the photoelectric conversion characteristics by the method for manufacturing a thin-film silicon solar cell according to the third embodiment.

As described above, in the method for roughening a solar cell substrate surface according to the third embodiment, the silicon dioxide thin film containing an amount of oxygen appropriately adjusted is formed as the etching resistant film 12. This enables to enhance adhesion of the etching resistant film 12 to the glass substrate 1a and suppress stripping of the etching resistant film 12, thereby forming deeper irregularities. Accordingly, the short-circuit current density Jsc can be improved relative to the case where the amorphous silicon is used in the first embodiment. Furthermore, by appropriately adjusting the oxygen content in the etching resistant film 12, film stripping of the etching resistant film 12 can be suppressed until a satisfactory texture is formed, and the etching resistant film 12 can be almost eliminated when the texture formation ends. This eliminates stripped film residues of the etching resistant film 12 in the etching solution and enables consecutive processing of etching.

### Fourth Embodiment

In a fourth embodiment of the present invention, a gradient composition film having a multilayer structure in which an oxygen content ratio in an early phase of film formation is set high and then oxygen content ratios are decreased during film formation on the glass substrate 1a, or a configuration in which the glass substrate 1a has large oxygen content and oxygen content is gradually decreased with increasing distance from the glass substrate 1a is formed as the etching resistant film 12. A roughened surface configuration of a substrate and a configuration of a thin-film silicon solar cell formed in the fourth embodiment are the same as those in the first embodiment. A manufacturing method according to the fourth embodiment is the same as that of the first embodiment except for a step of forming a silicon dioxide film as the etching resistant film 12.

As an example of the composition gradient, it is possible to simply form a silicon dioxide film on the side of the underlying glass substrate 1a and then form an amorphous silicon film containing no oxygen as an upper layer. By providing the silicon dioxide film in the etching resistant film 12 on the side of the glass substrate 1a, adhesion to the glass substrate 1a can be improved (suppression of stripping), and deeper irregularities can be formed during formation of the irregularities using hydrofluoric acid after opening formation. At the same time, by providing the amorphous silicon thin film on the side of the glass substrate 1a, a configuration that enables easy opening formation by laser can be realized.

At the step of forming the etching resistant film 12 in the fourth embodiment, the VHF plasma CVD at 60 kilohertz is used, a source material composed of silane gas, hydrogen gas, and carbon dioxide is flowed under conditions in which a substrate temperature is 170° C. and a gas pressure is 0.5 Torr, and flow rates of carbon dioxide are gradually decreased, for example. The flow rate of carbon dioxide is set at zero when a target thickness of 50 nanometers to 300 nanometers is obtained, and then the film formation is ended. After formation of the etching resistant film 12, the parabolic irregularities are formed on the glass substrate 1a and a thin-film silicon solar cell is formed in the same manner as in the first embodiment.

A thin-film silicon solar cell according to an Example 4 was formed by the method for manufacturing a thin-film silicon solar cell according to the fourth embodiment as described above. Short-circuit current densities Jsc (mA/cm²) of the thin-film silicon solar cell according to the Example 4 and of that according to the comparative example 1 of the first embodiment were compared.

As a result, the short-circuit current density of the thin-film silicon solar cell according to the Example 4 improved by about 6% relative to that of the thin-film silicon solar cell according to the comparative example 1. This confirmed an effect of improving the photoelectric conversion characteristics by the method for manufacturing a thin-film silicon solar cell according to the fourth embodiment.

### Fifth Embodiment

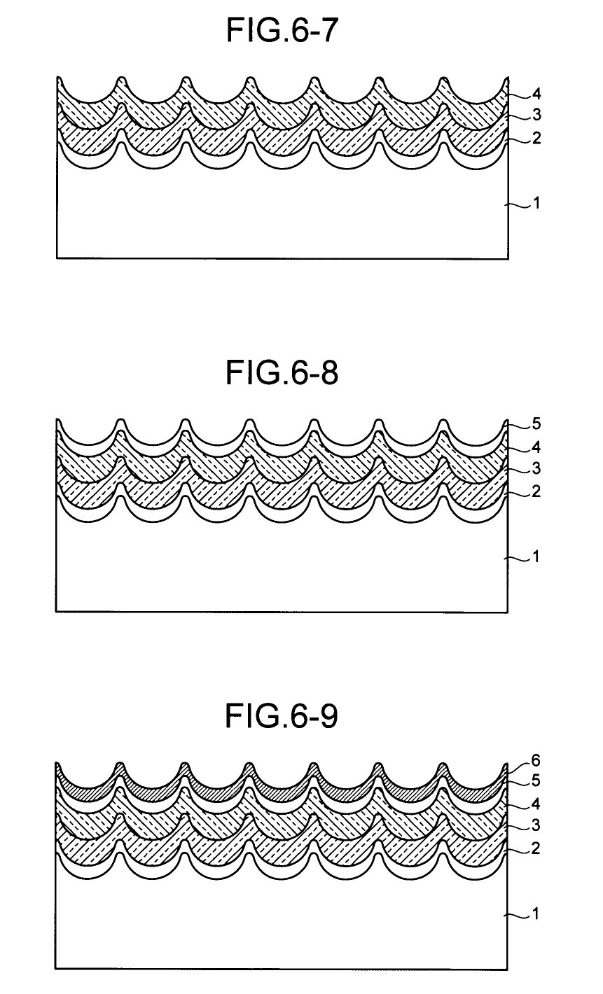

In a fifth embodiment of the present invention, a modification of the methods for manufacturing a thin-film silicon solar cell according to the first and second embodiments will be explained with reference to FIGS. 5 and 6-1 to 6-9. FIG. 5 is a flowchart for explaining a method for manufacturing a thin-film silicon solar cell according to the fifth embodiment. FIGS. 6-1 to 6-9 are cross-sectional views for explaining the method for manufacturing a thin-film silicon solar cell according to the fifth embodiment.

Processes at Steps S10 to S50 (FIGS. 6-1 to 6-5) are first executed to form the transparent electrode layer 2 made of a zinc oxide (ZnO) film by the sputtering method on the glass substrate 1 on which the parabolic irregularities having the substantially hemispherical texture depressions 11 arranged substantially uniformly are formed as the texture structure on a surface on one side. These processes are the same as those at Steps S10 to S50 (FIGS. 4-1 to 4-5) in the first embodiment.

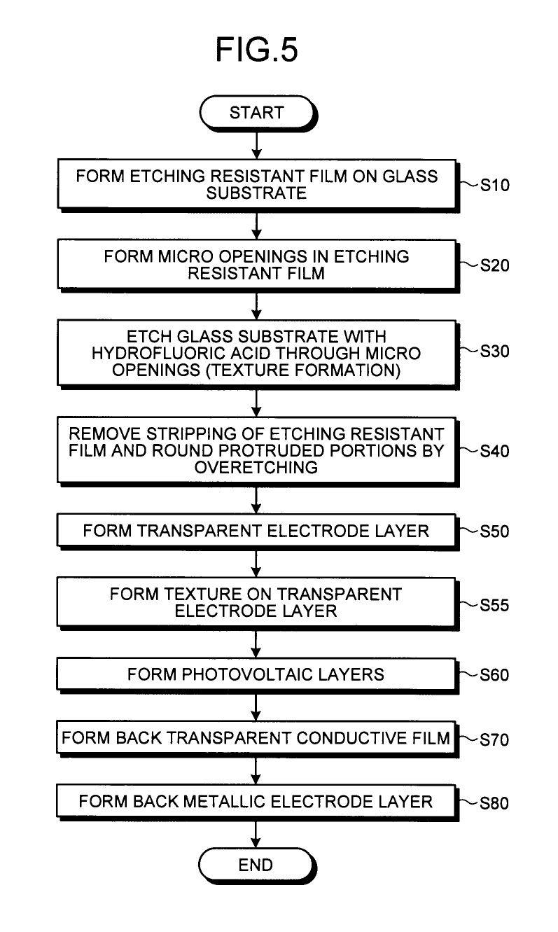

The surface of the transparent electrode layer 2 is dipped into an oxalic acid aqueous solution of 5 wt % to form minute irregularities smaller than the parabolic irregularities on the surface of the transparent electrode layer 2, thereby forming a texture structure on the surface of the transparent electrode layer 2 (Step S55, FIG. 6-6). It is assumed here that a height difference in the irregularities (an average of heights from bottoms of depressed portions to apexes of protruded portions) in the minute irregularities formed on the surface of the transparent electrode layer 2 is equal to or smaller than 1 micrometer, for example, that is, of submicron level. Processes at Steps S60 to S80 (FIGS. 6-6 to 6-9) are then executed, thereby manufacturing a thin-film silicon solar cell according to the fifth embodiment.

In the thin-film silicon solar cell according to the fifth embodiment thus manufactured, the texture structure of several micrometer level on the surface of the glass substrate 1 and the texture structure of submicron level on the surface of the transparent electrode layer 2 are combined, thereby achieving a more satisfactory light scattering effect on incident light, which lowers the optical reflectivity.

A thin-film silicon solar cell manufactured through the above steps (an Example 5) and a thin-film silicon solar cell having the same configuration as that of the thin-film silicon solar cell of the Example 5 except that no texture structures are formed on the glass substrate 1 and the transparent electrode layer 2 (a comparative example 2) were manufactured, and short-circuit current densities Jsc (mA/cm²) thereof were compared. As a result, the short-circuit current density of the thin-film silicon solar cell of the Example 5 improved by about 7% relative to that of the comparative example 2. This confirmed an effect of improving photoelectric conversion characteristics by the method for manufacturing a thin-film silicon solar cell according to the fifth embodiment.

As described above, in the thin-film silicon solar cell according to the fifth embodiment, the substantially hemispherical texture depressions 11 are provided substantially uniformly to form the parabolic irregularities as the texture structure on the surface of the glass substrate 1 on one side. With the texture structure of the parabolic irregularities, optical reflectivity is lowered and a satisfactory optical confinement effect is obtained.

In the thin-film silicon solar cell according to the fifth embodiment, the texture structure of submicron level is provided on the surface of the transparent electrode layer 2. Therefore, a more satisfactory light scattering effect on the incident light can be obtained, thereby lowering the optical reflectivity.

In the parabolic irregularities, the apexes of the protruded portions of the irregularities have rounded smooth shapes. This prevents occurrence of defects in the photovoltaic layers due to the texture structure and prevents reduction in the photoelectric conversion characteristics caused by the texture structure. Therefore, with the thin-film silicon solar cell according to the fifth embodiment, a thin-film silicon solar cell having high photoelectric conversion characteristics is realized.

In the method for manufacturing a thin-film silicon solar cell according to the fifth embodiment, the parabolic irregularities including the substantially hemispherical texture depressions 11 arranged substantially uniformly are formed as the texture structure on the surface of the glass substrate 1 on one side. The texture structure of the parabolic irregularities has low optical reflectivity and achieves a great optical confinement effect when a thin-film silicon solar cell is formed therewith.

In the method for manufacturing a thin-film silicon solar cell according to the fifth embodiment, the texture structure of submicron level is provided on the surface of the transparent electrode layer 2. Therefore, a more satisfactory light scattering effect on the incident light can be obtained, thereby lowering the optical reflectivity.

The rounding is performed through etching so that the apexes of the protruded portions in the parabolic irregularities have smooth and rounded shapes. This prevents occurrence of defects caused by the texture structure in the photovoltaic layers formed above the glass substrate 1 with the transparent electrode layer 2 interposed therebetween, and prevents reduction in the photoelectric conversion characteristics due to the texture structure. Therefore, with the method for manufacturing a thin-film silicon solar cell according to the fifth embodiment, a thin-film silicon solar cell having high photoelectric conversion characteristics can be manufactured.

### INDUSTRIAL APPLICABILITY

As described above, the method for roughening a substrate surface according to the present invention is useful for manufacturing a photovoltaic device having high photoelectric conversion efficiency.

### REFERENCE SIGNS LIST

1 GLASS SUBSTRATE
1a GLASS SUBSTRATE
2 TRANSPARENT ELECTRODE LAYER
3 FIRST PHOTOVOLTAIC LAYER
4 SECOND PHOTOVOLTAIC LAYER
5 BACK TRANSPARENT CONDUCTIVE FILM
6 BACK METALLIC ELECTRODE LAYER
11 TEXTURE DEPRESSION
12 ETCHING RESISTANT FILM
12a MICRO OPENING

1. A method for roughening a substrate surface comprising:
a first step of forming a protection film on a surface of a translucent substrate;
a second step of exposing the surface of the translucent substrate by forming a plurality of openings arranged regularly at a certain pitch in the protection film;
a third step of forming parabolic irregularities including substantially hemispherical depressions arranged substantially uniformly on the surface of the translucent substrate by performing isotropic etching by using the protection film having the openings formed as a mask and under conditions in which the protection film has resistance to the surface of the translucent substrate on which the protection film is formed; and
a fourth step of removing the protection film, wherein
at the fourth step, the isotropic etching is continued after formation of the parabolic irregularities to separate the protection film from the translucent substrate and round apexes of protruded portions in the parabolic irregularities.

2. The method for roughening a substrate surface according to claim 1, wherein
the translucent substrate is a glass substrate,
the protection film is a silicon thin film or a thin film of silicon compound, and
at the second step, the openings are formed in the protection film by applying a laser beam to the protection film.

3. The method for roughening a substrate surface according to claim 2, wherein
the laser beam used in the laser processing has a spot diameter of 1 micrometer to 5 micrometers, and
the openings have a pitch of 2 micrometers to 10 micrometers.

4. The method for roughening a substrate surface according to claim 1, wherein
the translucent substrate is a glass substrate,
the protection film is a silicon thin film or a thin film of silicon compound, and
at the second step, the openings are formed in the protection film by sandblasting the protection film.

5. The method for roughening a substrate surface according to claim 1, wherein
the translucent substrate is a glass substrate, and
an etching solution used in the isotropic etching is hydrofluoric acid.

6. The method for roughening a substrate surface according to claim 1, wherein
the translucent substrate is a glass substrate, and
the protection film is a silicon compound thin film containing oxygen.

7. The method for roughening a substrate surface according to claim 1, wherein
the translucent substrate is a glass substrate, and
the protection film is a laminated film including a silicon thin film containing oxygen and an amorphous silicon film containing no oxygen laminated in this order from a side of the glass substrate.

8. The method for roughening a substrate surface according to claim 1, wherein
the translucent substrate is a glass substrate, and
the protection film is a silicon thin film in which oxygen content decreases with increasing distance from the glass substrate.

9. A method for manufacturing a photovoltaic device comprising:
a surface roughening step of roughening one surface of a translucent substrate by the method for roughening a substrate surface according to claim 1;
a first-electrode-layer forming step of forming a first electrode layer comprising a transparent conductive film on the surface of the translucent substrate;
a photovoltaic-layer forming step of forming a photovoltaic layer that comprises a semiconductor film and performs photoelectric conversion on the first electrode layer; and
a second-electrode-layer forming step of forming a second electrode layer comprising a conductive film that reflects light on the photovoltaic layer.

10. The method for manufacturing a photovoltaic device according to claim 9, wherein at the first-electrode-layer forming step, irregularities smaller than the parabolic irregularities are formed on a surface of the first electrode layer.

11. A photovoltaic device comprising a first electrode layer that comprises a transparent conductive layer, a photovoltaic layer that comprises a semiconductor film and performs photoelectric conversion, and a second electrode layer that comprises a conductive film reflecting light laminated in this order on a translucent substrate, wherein
parabolic irregularities including substantially hemispherical depressions arranged substantially uniformly are formed on a principal surface of the translucent substrate on a side of the first electrode layer, and apexes of protruded portions in the irregularities are in rounded shapes.

12. The photovoltaic device according to claim 11, wherein irregularities smaller than the parabolic irregularities are formed on a surface of the first electrode layer.
